(19) United States
(12) Patent Application Publication
(10) Pub. No.: US 2003/0024808 A1
(43) Pub. Date: Feb. 6, 2003

(54) Methods of sputtering using krypton

(76) Inventors: Hilke Donohue, Cardiff (GB); Mark Graeme Martin Harris, Caerlton (GB)

Correspondence Address: Volentine Francos, Suite 150, 12200 Sunrise Valley Drive, Reston, VA, 20191, US

(21) Appl. No.: 10/204,247

(22) PCT Filed: Dec. 21, 2001
(86) PCT No.: PCT/GB01/05795

(30) Foreign Application Priority Data
Jan. 4, 2001 (GB) 0100151.0

(51) Int. Cl. C23C 14/34

(52) U.S. Cl. 204/192.17; 204/192.12

(57) ABSTRACT

A method of sputtering a layer from a target having a plurality of recesses or openings includes using Krypton as a sputtering gas and is characterized in that the gas flow is less than 20 sccm and or the Krypton pressure is less than 1 militor.

This invention relates to methods of sputtering a layer on a substrate having a plurality of submicron sized recesses or openings.

As the dimensions of features on semiconductor devices, and other substrates, get progressively smaller, it becomes progressively more difficult to get effective coverage at the base of holes or recesses in the substrates when depositing sputtered layers. Quite a usual representation of degree of success is to plot the ratio of the thickness of the layer B deposited at the base of such a hole or recess against the thickness F of layer deposited on the field or upper surface of the substrate. There are various techniques that can be used to improve this ratio. One is to bias the substrate. The second is to include a collimator or to separate the target and substrate sufficiently for most of the atoms reaching the substrate to be travelling in a direction normal to the surface of the substrate. This is sometimes known as a “long throw” configuration. However, it is generally the case that if, by collimation or the use of a long throw configuration, one had ensured that the vast majority of atoms are travelling normal to the surface of the substrate when they reach the substrate.

A third technique is to ionise the sputtered material either by an ionising coil, or by using high power levels to the sputter target. These techniques may be used individually but more generally in combination with one another.

From one aspect the invention consists in a method of sputtering a layer on the substrate having plurality of recesses or openings including using krypton as the sputtering gas characterised in that the gas flow is less than 20 sccm and/or the krypton pressure is less than 1.0 mTorr.

Previously it might have been considered that at very low working gas pressures the rate of material deposition would be so low as to badly effect through-put times. However, the applicants have discovered that in their configuration a pressure of as low as 0.15 millitorr for krypton produces a significantly better B/F ratio, which thus compensates at least in part for any loss of overall rate of deposition.

Further, the applicants have determined that the B/F ratio can further be improved at these low pressures by negatively biasing the substrate, although, currently, they are unable to offer an explanation for this effect as the meanfree path of the working gas already significantly exceeds the source to substrate distance.

In the preferred arrangement the target/substrate separation will be at least 200 mm and preferably over 400 mm and most preferably between 400 & 450 mm. The method may additional or alternatively include the use of the collimator disposed between the target and the substrate.

Although the invention has been defined above it is to be understood that it includes any inventive combination of the features set out above or in the following description.

The invention may be performed in various ways and a specific embodiment will now be described, by way of example, with reference to the accompanying drawings, in which:

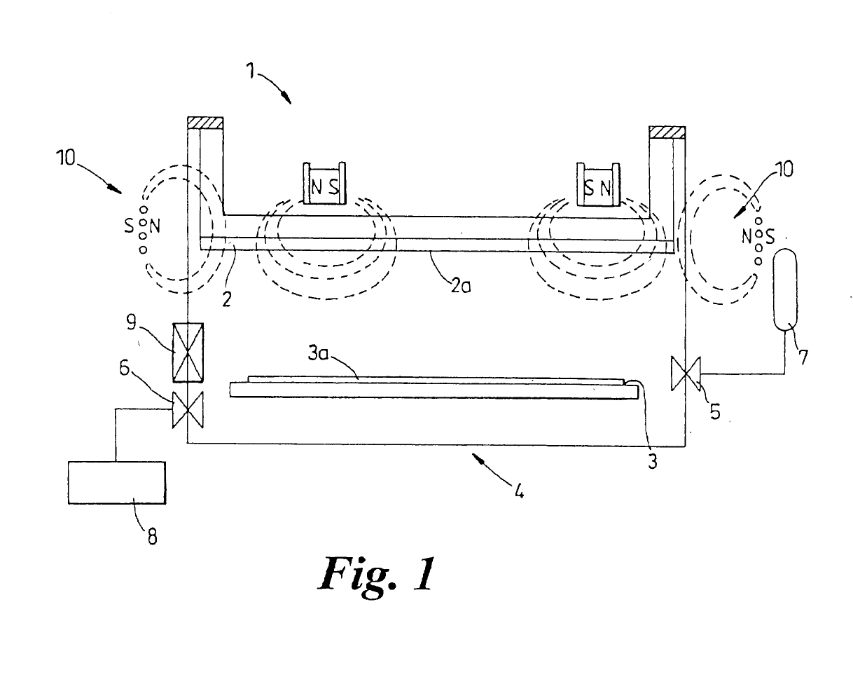

FIG. 1 is a schematic view of an apparatus for performing a method of sputtering;

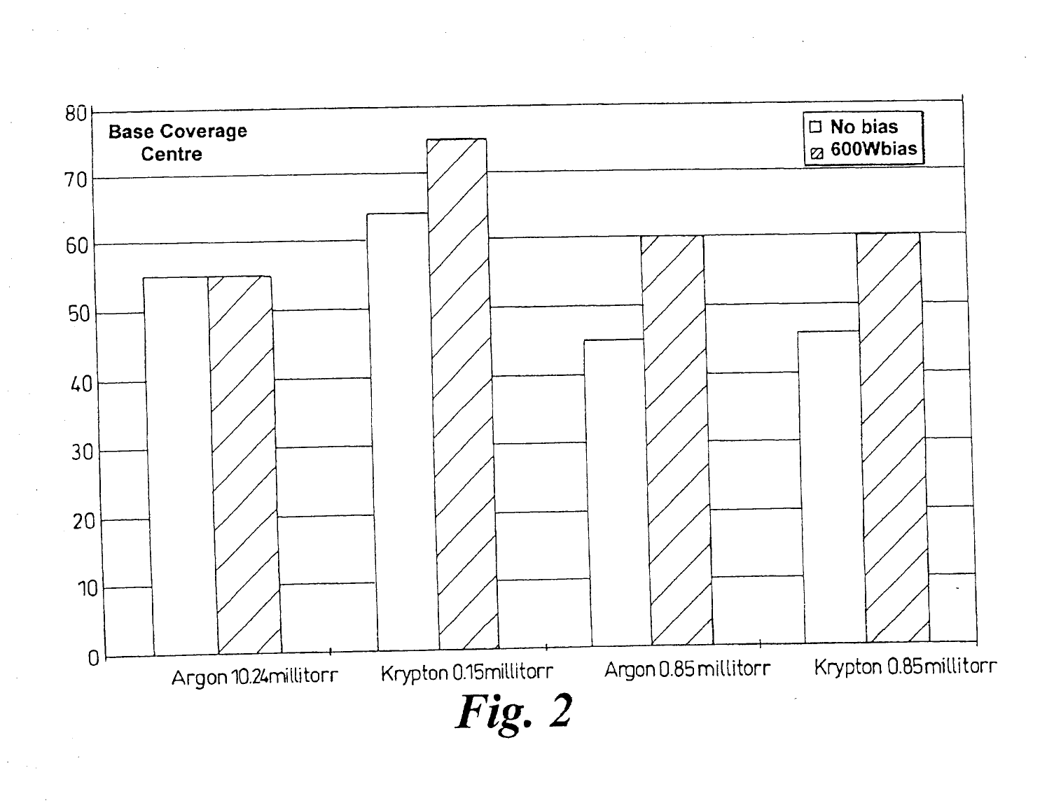

FIG. 2 is a bar chart indicating the B/F ratio achieved for various sputtering conditions at the centre of the substrate; and

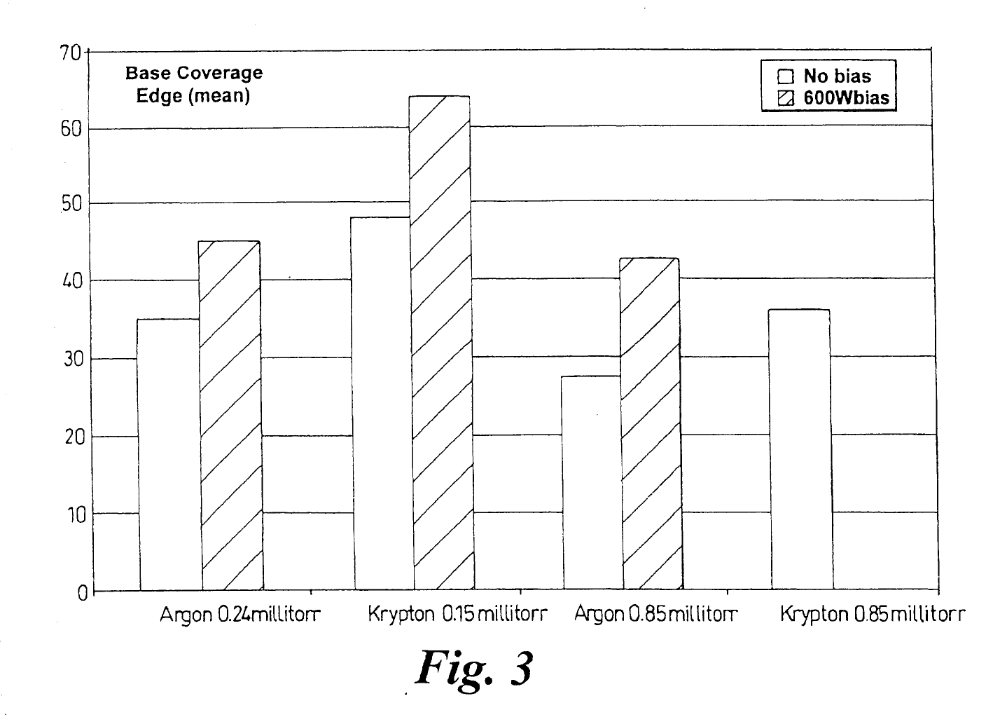

FIG. 3 is the corresponding chart for features at the edge of the substrate.

In FIG. 1, a target 2 and substrate support 3 are each contained within a vacuum low pressure vessel in the form of chamber 4 through which a gas can be streamed at low pressure via an inlet valve 5 and an outlet valve 6 from a respective gas source reservoir 7 and a vacuum pump 8. A substrate 3a can be placed on the substrate support 3 via a door 9. Plasma is confined by the coil assembly 10 thus enabling lower pressure operation at any given target voltage by lowering the plasma impedance. (A moving magnetron assembly 1 is associated with the target 2 that is powered by a power supply 11. The wafer may be biased by power supply 12. A detailed explanation of the operation of such a chamber is contained in our co-pending application 0021754.7, the content of which is hereby incorporated by reference.

In the experiments carried out for the present application the experimental set up was as follows:

| | |
|---|---|
| Target to wafer | 430 mm (source to substrate distance) |
| Coil Power | 140 amps DC to 8 turn coil (1,120 |
| | ampere turns) |
| Target Power | 30 kW, DC |
| Gas flows | See FIGS. 2 and 3 |
| Resultant pressures | 0.24 mTorr Argon for 9 sccm flow |
| | ratio |
| | 0.15 mTorr Krypton for 2 sccm flow ratio |
| Process time | 70 seconds |
| Platen bias | 600 Watts 13.56 meg RF, inducing 135 v |
| | dc. when applied |
| Platen temp | 200° C. |

It should be noted that the wafers were unclamped and, at these low pressures, the thermal conduction would have been poor. Accordingly, the actual wafer temperature would be significantly less than the indicated platen temperature.

Turning to FIGS. 2 and 3, it will be seen that plots have been created for single experiments at various flow/pressure conditions of argon and krypton, with and without bias. The BF/ratio is expressed as a percentage.

In FIG. 2 at 0.85 millitorr there is no discernible difference between krypton and argon, although, at the edge, as shown in FIG. 3, the base coverage produced by krypton, in a non bias set up, is an improvement on the argon case. At 0.24 millitorr pressure of Argon (the minimum that can be achieved with argon in the set up utilised) the B/F percentage had improved.

Switching to Krypton enables lower pressure operation ˜0.15 millitorr was possible with the experimental target power supply. A considerably improved B/F percentage was achieved. This is not a predictable result. Theoretical calculations show that at 0.24 millitorr the mean free path of an Argon ion is 53 cm—already comfortably exceeding the source to substrate distance of 43 cm. No further improvement would therefore be expected from further reduced pressure operation. However at 0.15 millitorr, Krypton provides a significant improvement to the base coverage percentage. This lower pressure operation is most conveniently achieved by the use of Krypton as it enables lower voltage operation without special plasma ignition devices and/or high voltage power supplies that would be required for argon operation.

1. A method of sputtering from a target a layer onto a substrate having a plurality of recesses or openings including using krypton as the sputtering gas characterised in that the gas flow is less than 20 sccm and/or the krypton pressure is less than 1.0 millitorr.

2. A method as claimed in claim 1 wherein the krypton pressure is less than 0.5 millitorr.

3. A method as claimed in claim 2 wherein the krypton pressure is less than 0.25 millitorr.

4. A method as claimed in claim 3 wherein the krypton pressure is about 0.5 millitorr.

5. A method as claimed in any one of the preceding claims wherein the substrate is negatively biased.

6. A method as claimed in any one of the preceding claims wherein the target/substrate separation is greater than 200 mm.

7. A method as claimed in claim 6 wherein the target/substrate separation is greater than or equal to 400 mm.

8. A method as claimed in claim 7 wherein the target/substrate separation is between 400 and 450 nm.

9. A method as claimed in any one of the preceding claims including a collimator disposed between the target and the substrate
